(19) United States
(12) Patent Application Publication
(10) Pub. No.: US 2007/0035039 A1
(43) Pub. Date: Feb. 15, 2007

(54) Overlay marker for use in fabricating a semiconductor device and related method of measuring overlay accuracy

(76) Inventor: Kang Hyun-Tae, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/485,322

(22) Filed: Jul. 13, 2006

(30) Foreign Application Priority Data
Aug. 10, 2005 (KR) 10-2005-0073305

(51) Int. Cl. H01L 23/28

(52) U.S. Cl. 257/787

(57) ABSTRACT

An overlay marker adapted for use in fabricating a semiconductor device and a method of measuring overlay accuracy using the overlay marker are disclosed. The semiconductor device comprises sequentially disposed first, second, and third material layers, and the overlay marker comprises a primary marker and a secondary marker. The primary marker comprises a first pair of primary markers oriented in a first direction and disposed facing each other on the first material layer, and a second pair of primary markers oriented in a second direction and disposed facing each other on the second material layer. The secondary marker is disposed on the third material layer and comprises a first pair of secondary markers and a second pair of secondary markers.

### BACKGROUND OF THE INVENTION

1. Field of the Invention

Embodiments of the invention relate to an overlay marker for use in fabricating semiconductor devices and a method of measuring overlay accuracy using the overlay marker. In particular, embodiments of the invention relate to an overlay marker and a method of measuring overlay accuracy using the overlay marker and multiple operations of setting a focal plane.

This application claims priority to Korean Patent Application No. 2005-0073305, filed on Aug. 10, 2005, the subject matter of which is hereby incorporated by reference in its entirety.

2. Description of the Related Art

Semiconductor devices have developed rapidly along with expansions in the field of information technology and the increasing popularity of information technology devices such as computers. Continuing demand for semiconductor devices with faster operating speeds and greater storage capacities has lead to an increase in the integration density of semiconductor devices. As integration densities for semiconductor devices have increased, the size of individual components forming the increasingly dense semiconductor devices has decreased. Further, semiconductor devices formed as multi-layer structures and characterized by multiple circuit patterns formed within a relatively limited surface are now widely used.

As a result, two general methods of implementing a multi-layer structure are widely used. The first is a double layer process in which multiple metal layers are selectively connected using metal via-contacts. The second is a multi-layer transistor process in which more than two transistors are formed on a semiconductor substrate in vertical alignment.

Memory devices are convenient examples of highly dense semiconductor devices. Within contemporary memory devices, the memory cell region is much more densely integrated than the corresponding peripheral circuit region. Thus, as the integration density of a memory device generally increases, so does the material layer step difference (i.e., a height difference) between adjacent patterns of a memory device related to these two disparate regions. At some level, a large enough step difference creates problems in the fabrication process (e.g., an inability to effectively cover the step with a commonly formed layer). Further, it is difficult to etch a pattern with an exact profile because of the increasingly low relative resolution of conventional photo-etching equipment. Additionally, as integration density increases, the overall process margin for circuit patterns forming the semiconductor device shrinks to the point where pattern misalignment becomes an increasing problem.

In order to minimize misalignment between patterns formed (e.g., through a photo-etching process) during the fabrication of semiconductor devices, the overlay relationship between a first marker (e.g., a lower marker formed on a lower material layer) and a second marker (e.g., an upper marker formed on an upper or overlaying material layer), is commonly referenced. Hence, the overlay accuracy between the lower layer and the upper layer is an important factor in determining the yield of semiconductor devices as well as semiconductor device reliability. One type of overlay mark adapted for use in measuring overlay accuracy and a related method of measuring overlay accuracy using the overlay mark is disclosed in U.S. Pat. No. 6,440,262 and U.S. Pat. No. 6,083,807, the subject matter of which is hereby incorporated by reference.

In one conventional approach, overlay accuracy is measured using an overlay marker comprising an outer marker and an inner marker. This type of overlay marker is typically formed in a scribe region of a wafer, so that it does not interfere with the operation of functional circuits in the semiconductor device.

Figure (FIG.) 1 shows a conventional overlay marker. Referring to FIG. 1, a reference symbol 12 indicates an outer marker, and a reference symbol 16 indicates an inner marker. The overlay marker comprises outer marker 12 and inner marker 16. Respective centers of outer marker 12 and inner marker 16 are detected, respectively. In addition, the overlay accuracy between a first marker and a second marker formed subsequently is measured in accordance with the difference between the centers of outer marker 12 and inner marker 16.

The overlay accuracy between outer marker 12 and inner marker 16 is optically measured using an overlay measurement apparatus. That is, the overlay accuracy between outer marker 12 and inner marker 16 is measured by using an optical microscope to measure the difference between the respective centers of outer marker 12 and inner marker 16, which is formed after outer marker 12 has been formed. This method of measuring the overlay accuracy will be described in more detail with reference to FIGS. 2 and 3.

FIG. 2 is a cross-sectional view of the overlay marker of FIG. 1 viewed along a line A-A′ of FIG. 1.

Referring to FIG. 2, a first pair of outer markers 12 is formed by performing a typical photo-etching process on a semiconductor substrate 10. Outer marker 12 of FIG. 1 comprises the first pair of outer markers 12 formed on semiconductor substrate 10.

In addition, an interlayer insulation film 14 is formed on semiconductor substrate 10, comprising the first pair of outer markers 12, using SiO₂ or SiON. Then, a photoresist layer is formed on interlayer insulation film 14 and then patterned to form a first pair of outer markers 16, wherein inner marker 16 of FIG. 1 comprises the first pair of outer markers 16.

Further, a gate of an apparatus (not shown) adapted for measuring the overlay accuracy is disposed in a common area B (see FIG. 1) of outer marker 12 and inner marker 16 of FIG. 1, and laser light 18 is radiated onto the resultant structure to measure the overlay accuracy. As a result, as shown in FIG. 2, the light is scattered and reflected by the edges of the markers of the first pair of outer markers 12 and the first pair of inner markers 16. The light scattered by the edges of the markers mentioned above does not enter a photo sensor of the overlay measurement apparatus, and waveforms as shown in FIGS. 3 and 4 are thereby obtained from the optical sensor.

When radiating light 18, the focal plane (i.e., the focal plane of the overlay measurement apparatus) is respectively set in accordance with outer marker 12 and inner marker 16. FIG. 3 illustrates an exemplary waveform produced when the focal plane is set in accordance with outer marker 12. When the focal plane is set in accordance with outer marker 12, outer marker 12 is detected with high resolution and waveforms 22a and 22b, which correspond to the first pair of outer markers 12, are distinctly output as shown in FIG. 3, and the center of a distance C between waveform 22a and waveform 22b may be measured.

FIG. 4 illustrates an exemplary waveform produced when the focal plane is set in accordance with inner marker 16. When the focal plane is set in accordance with inner marker 16, inner marker 16 is detected with high resolution and waveforms 24a and 24b, which correspond to the first pair of inner markers 16, are distinctly output as shown in FIG. 4, and the center of a distance D between waveform 24a and waveform 24b may be measured.

In addition, the overlay accuracy of outer marker 12 and inner marker 16 is measured by detecting an error (i.e., a difference) between the centers of outer marker 12 and inner marker 16.

To obtain the overlay accuracy of outer and inner markers by measuring the distance between the centers of the outer marker and the inner marker, it is necessary to find an exact focal position for radiating light onto the overlay marker. Thus, as described above, the focal plane, which is a reference of focus, is respectively set in accordance with outer marker 12 and inner marker 16. Next, exact focus points are found, and centers of the outer marker and the inner marker are measured, and the overlay accuracy of the overlay marker may thereby be obtained.

The conventional art only measures the overlay accuracy between two markers: a first marker (i.e., a lower marker) and a second marker (i.e., an upper marker), as described above with reference to FIGS. 1 through 4. However, there are situations in which the overlay accuracy between more than two sets of patterns needs to be measured. If the overlay accuracy of a plurality of markers respectively formed on three different layers is measured in accordance with the conventional art, the focal plane will only be respectively set in accordance with two of the three markers, so only a weak signal will be obtained for the third marker (i.e., the marker for which the focal plane is not set). Thus, the conventional art may incorrectly measure overlay accuracy for more than two markers.

### SUMMARY OF THE INVENTION

Embodiments of the invention provide an overlay marker and a method of precisely measuring the overlay accuracy of primary and secondary markers having patterns formed on a total of more than two different layers using the overlay marker.

In one embodiment, the invention provides an overlay marker adapted for use in fabricating a semiconductor device, the semiconductor device comprising sequentially disposed first, second, and third material layers, and the overlay marker comprising a primary marker and a secondary marker. The primary marker comprises a first pair of primary markers oriented in a first direction and disposed facing each other on the first material layer, and a second pair of primary markers oriented in a second direction and disposed facing each other on the second material layer. The secondary marker is disposed on the third material layer and comprises a first pair of secondary markers disposed facing each other between the first pair of first primary markers and in parallel with the first pair of primary markers, and a second pair of secondary markers disposed facing each other between the second pair of primary markers and in parallel with the second pair of primary markers.

In another embodiment, the invention provides an overlay marker adapted for use in fabricating a semiconductor device, the semiconductor device comprising sequentially disposed first, second, and third material layers, and the overlay marker comprising a primary marker and a secondary marker. The primary marker comprises a first pair of primary markers oriented in a first direction and disposed facing each other on the first material layer, and a second pair of primary markers oriented in a second direction and disposed facing each other on the second material layer. The secondary marker is disposed on the third material layer and comprises a first pair of secondary markers disposed facing each other between the first pair of first primary markers and in parallel with the first pair of primary markers, and a second pair of secondary markers disposed facing each other between the second pair of primary markers and in parallel with the second pair of primary markers. The method comprises finding a center of the primary marker, finding a center of the secondary marker, and finding an error between the between the center of the primary marker and the center of the secondary marker.

### BRIEF DESCRIPTION OF THE DRAWINGS

Embodiments of the invention will be described with reference to the accompanying drawings, in which like reference symbols refer to like or similar elements throughout. In the drawings:

FIG. 1 is a plan view of a conventional overlay marker;

FIG. 2 is a cross-sectional view of the overlay marker of FIG. 1 viewed along line A-A′ of FIG. 1;

FIG. 3 is a graph illustrating an exemplary waveform produced when the focal plane is set in accordance with outer marker 12 of FIG. 1;

FIG. 4 is a graph of illustrating an exemplary waveform produced when the focal plane is set in accordance with inner marker 16 of FIG. 1;

FIG. 5 is a plan view of an overlay marker in accordance with an embodiment of the invention;

FIG. 6 is a cross-sectional view of the overlay marker of FIG. 5 viewed along a line E-E′ of FIG. 5.

FIG. 7 is a cross-sectional view of the overlay marker of FIG. 5 viewed along a line F-F′ of FIG. 5.

FIG. 8 is a graph showing an exemplary waveform produced when the focal plane is set in accordance with a first pair of primary markers 102 of FIG. 5;

FIG. 9 is a graph showing an exemplary waveform produced when the focal plane is set in accordance with a second pair of primary markers 106 of FIG. 5;

FIG. 10A is a graph showing an exemplary waveform produced when the focal plane is set in accordance with a first pair of secondary markers 110 of FIG. 5; and,

FIG. 10B is a graph showing an exemplary waveform produced when the focal plane is set in accordance with a second pair of secondary markers 110 of FIG. 5.

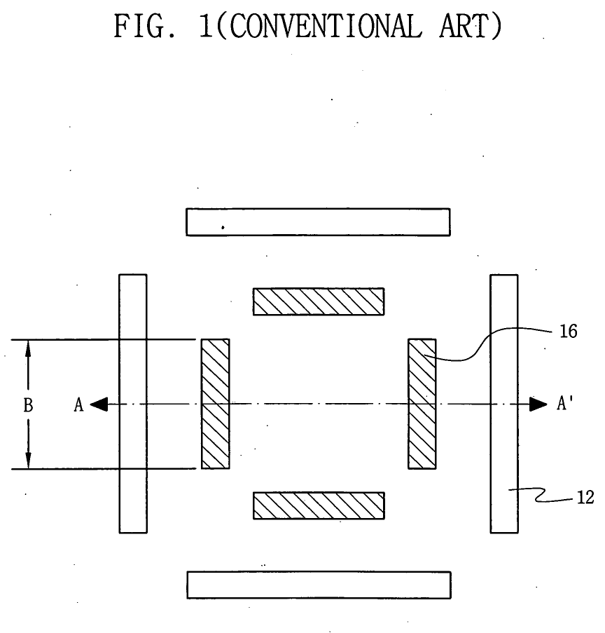

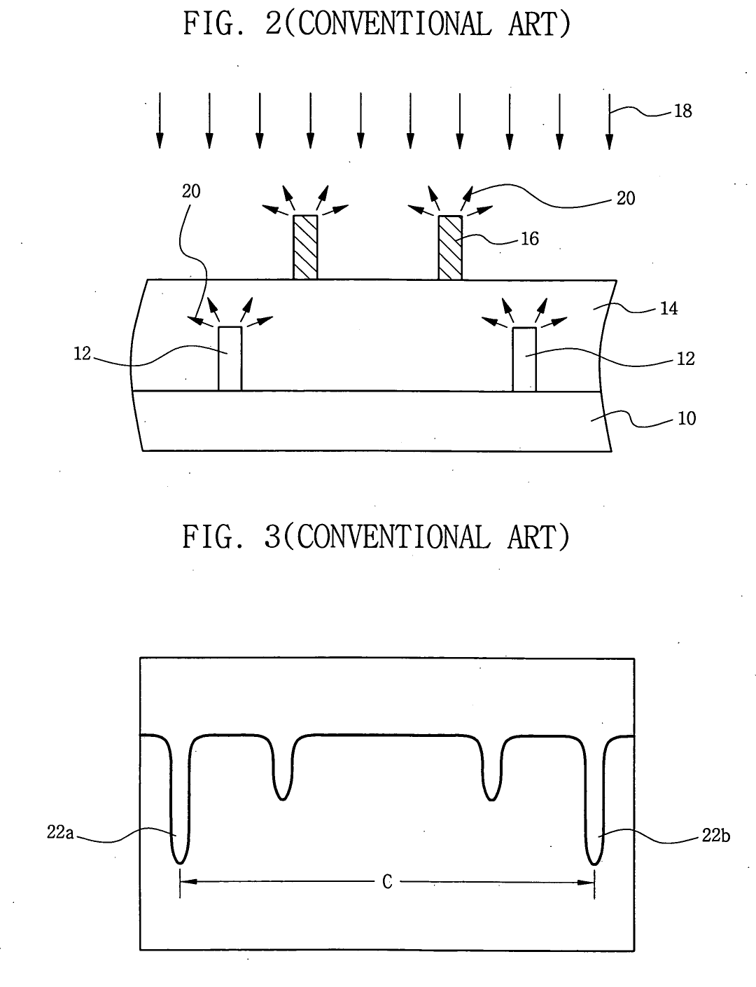

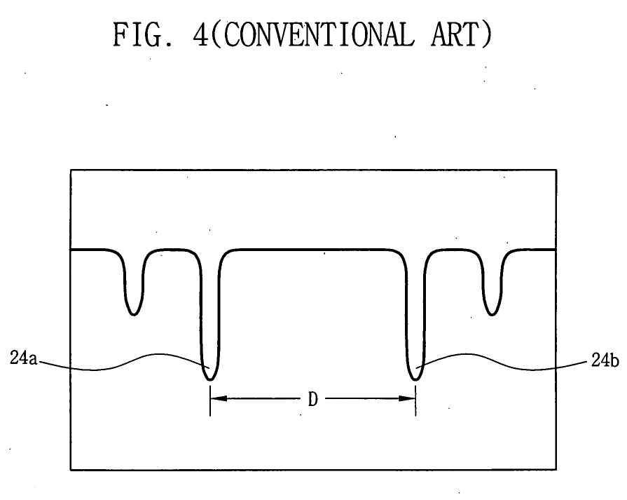

### DESCRIPTION OF EMBODIMENTS

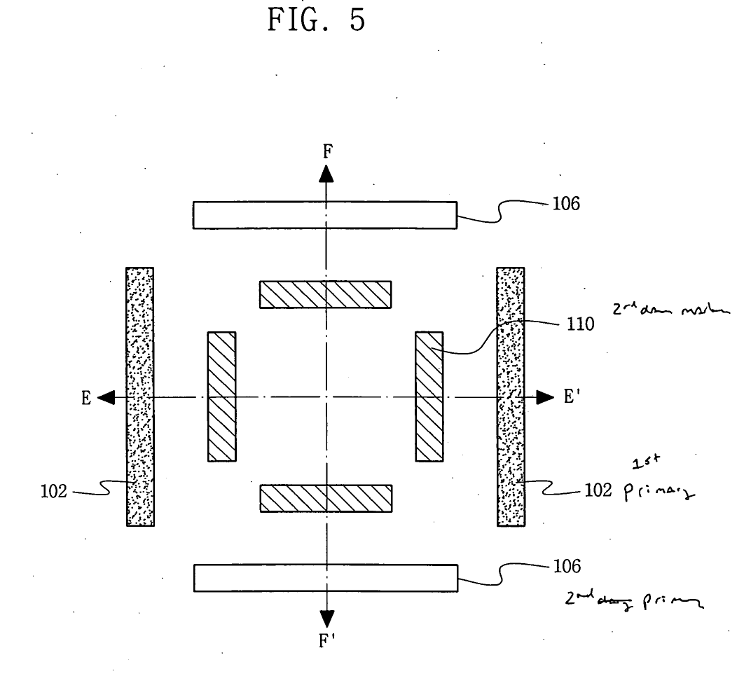

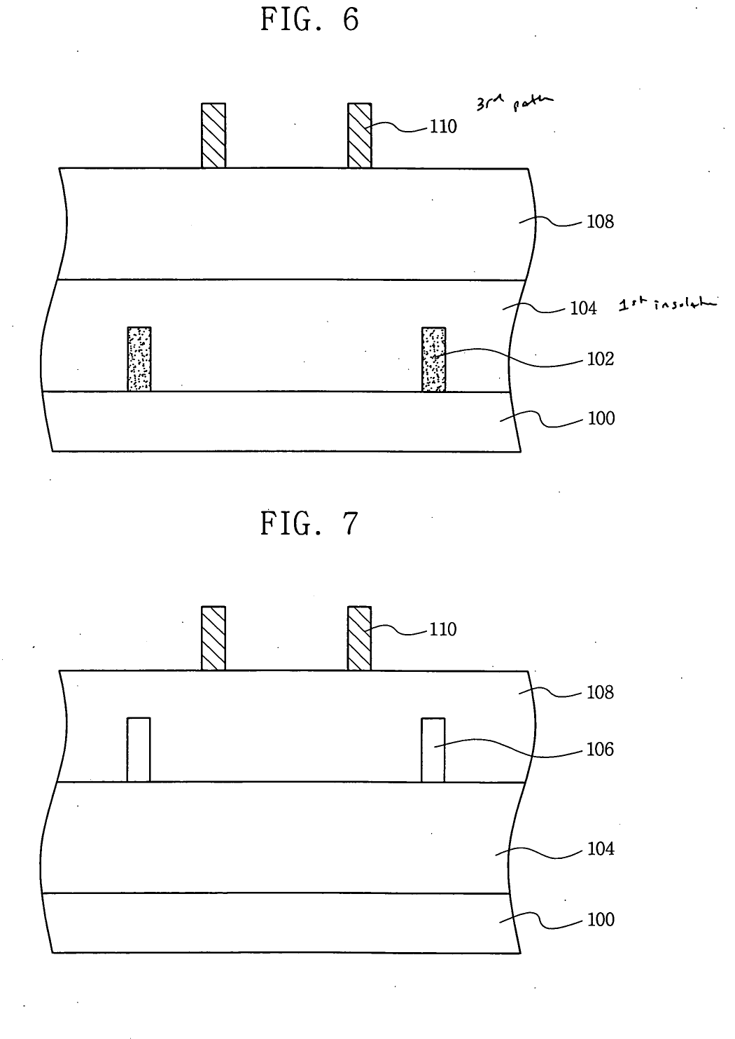

FIG. 5 shows an overlay marker in accordance with an embodiment of the invention. FIG. 6 is a cross-sectional view of the overlay marker of FIG. 5 viewed along a line E-E′ of FIG. 5. FIG. 7 is a cross-sectional view of the overlay marker of FIG. 5 viewed along a line F-F′ of FIG. 5.

Referring to FIG. 5, an overlay marker is formed wherein the overlay marker comprises a primary marker 102, 106 comprising a first pair of primary markers 102, a second pair of primary markers 106, a secondary marker 110. The first pair of primary markers 102 is oriented in a first direction, and the second pair of primary markers 106 is oriented in a second direction and is formed on a different layer (e.g., a second material layer) than the layer on which the first pair of primary markers 102 is formed (e.g., a first material layer). Also, the first and second directions are orthogonal. In addition, secondary marker 110 is formed on a different layer than each of the first pair of primary markers 102 and the second pair of primary markers 106 (i.e., secondary marker 110 is formed on a third material layer).

Referring to FIGS. 6 and 7, the first pair of primary markers 102 may be formed by photo-etching a semiconductor substrate 100. Alternatively, the first pair of primary markers 102 may be formed by photo-etching a (first) material layer formed on semiconductor substrate 100. The first pair of primary markers 102 may be formed from a conductive layer such as a polysilicon layer. Next, a first interlayer insulation film 104 is formed by depositing SiO₂ or SiON at a thickness of 100-300 Å on semiconductor substrate 100 on which the first pair of primary markers 102 is formed. In addition, the second pair of primary markers 106 is typically formed by photo-etching first interlayer insulation film 104. Alternatively, the second pair of primary markers 106 may be formed on first interlayer insulation film 104 by photo-etching a material layer formed on first interlayer insulation film 104. The second pair of primary markers 106 may be formed from a conductive layer such as a polysilicon layer. Next, a second interlayer insulation film 108 is formed by depositing SiO₂ or SiON at a thickness of 100-300 Å on semiconductor substrate 100 on which the second pair of primary markers 106 is formed. Further, a photoresist layer is then formed on second interlayer insulation film 108 and secondary marker 110 is formed by photo-etching the photoresist layer. As used herein, when a first element or layer is said to be formed “on” a second element or layer, the first element or layer may be formed directly on the second element or layer, or intervening elements or layers may be present.

Secondary marker 110 comprises first and second pairs of secondary markers 110, and secondary marker 110 may be formed inside or outside of primary marker 102,106.

Because FIG. 6 shows a cross-section of the overlay marker of FIG. 5 viewed along line E-E′ of FIG. 5, the second pair of primary markers 106 is not visible in FIG. 6. Likewise, because FIG. 7 shows a cross-section of the overlay marker of FIG. 5 viewed along line F-F′ of FIG. 5, the first pair of primary markers 102 is not visible in FIG. 7.

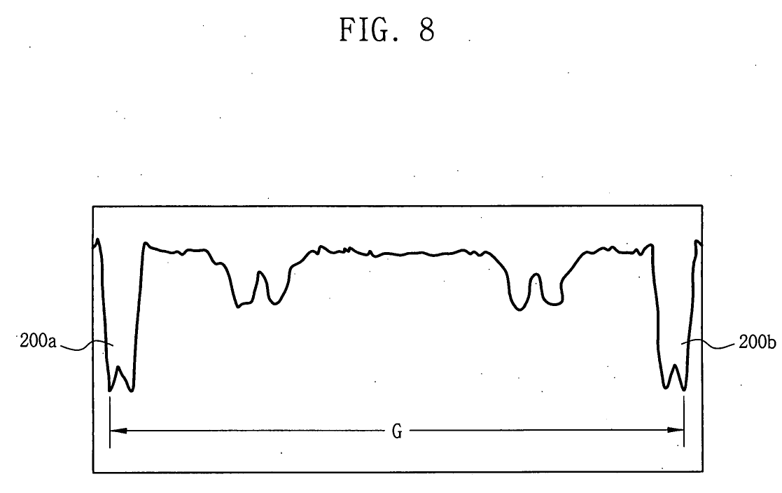

To measure the overlay accuracy between primary marker 102, 106 and secondary marker 110, the center position of primary marker 102, 106 (i.e., the entire primary marker 102, 106) is measured by respectively setting the focal plane (i.e., the focal plane of the overlay measurement apparatus), which is a reference of focus, in accordance with the first pair of primary markers 102 and the second pair of primary markers 106, and then measuring the respective centers of the first pair of primary markers 102 and the second pair of primary markers 106. Next, the overlay accuracy between primary marker 102, 106 and secondary marker 110 is measured by detecting the difference (i.e., an error) between the centers of primary marker 102, 106 and secondary marker 110. A visible ray, such as a g-line (436 nm) or a green light (547 nm), may be used as the light source adapted for radiating light on the focal plane. Alternatively, a laser light, such as a He-Ne laser (633 nm) or a He-Cd laser (442 nm), may be used as the light source adapted for radiating light on the focal plane. A method of measuring the overlay accuracy in accordance with an embodiment of the invention will now be described with reference to FIGS. 8 through 10.

FIG. 8 shows an exemplary first waveform produced when the focal plane is set in accordance with the first pair of primary markers 102. When the focal plane is set in accordance with the first pair of primary markers 102, the first pair of primary markers 102 is detected with high resolution when light is radiated onto the substrate (i.e., radiated on the focal plane). As a result, distinct waveforms (200a, 200b) corresponding to the first pair of primary markers 102, as shown in FIG. 8, are output. A center position of a distance G between waveforms 200a and 200b, which correspond to the first pair of primary markers 102, is then measured, yielding a center position of the first pair of primary markers 102.

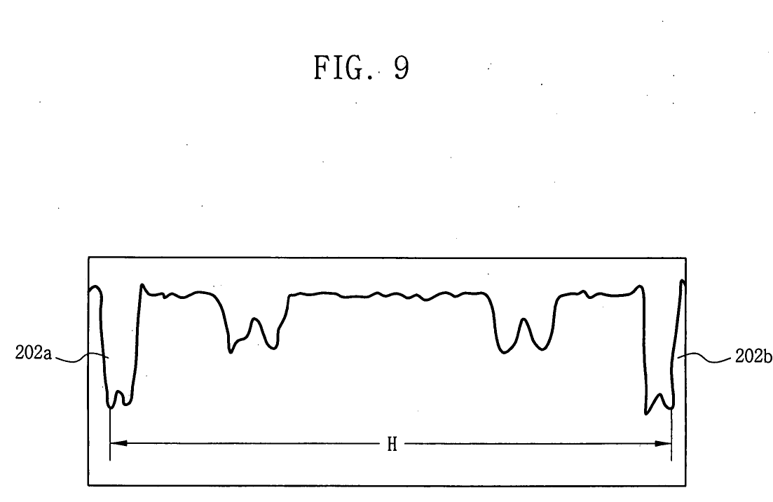

FIG. 9 shows an exemplary second waveform produced when the focal plane is set in accordance with the second pair of primary markers 106. When the focal plane is set in accordance with the second pair of primary markers 106, the second pair of primary markers 106 is detected with high resolution when light is radiated onto the substrate (i.e., radiated on the focal plane). As a result, distinct waveforms 202a and 202b corresponding to the second pair of primary markers 106, as shown in FIG. 9, are output. A center position of a distance H between waveforms 202a and 202b, which correspond to the second pair of primary markers 106, is then measured, yielding a center position of the second pair of primary markers 106. In addition, the center of primary marker 102, 106 (i.e., the entire primary marker 102, 106) is measured by correlating (e.g., adding) the center position of the first pair of primary markers 102 and the center position of the second pair of primary markers 106.

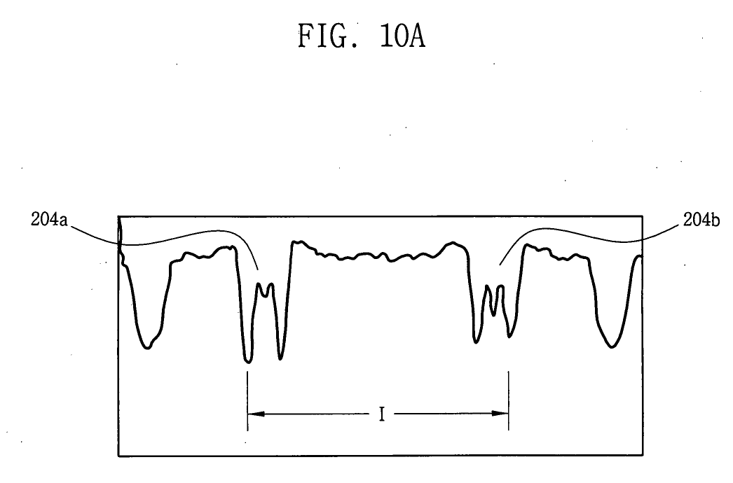

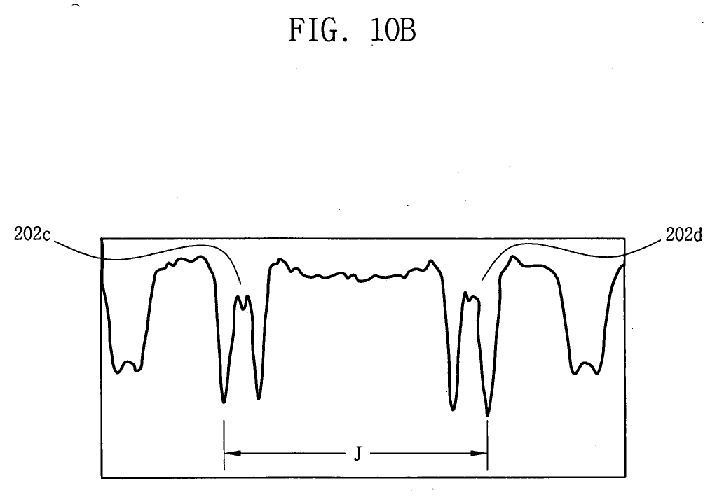

FIGS. 10A and 10B show exemplary waveforms produced when the focal plane is set in accordance with respective pairs of secondary markers 110 of secondary marker 110. FIG. 10A is a graph showing an exemplary third waveform corresponding to the first pair of secondary markers 110 formed parallel to the first pair of primary markers 102, and reference symbols 204a and 204b respectively indicate waveforms corresponding to the first pair of secondary markers 110. FIG. 10B is a graph showing an exemplary fourth waveform corresponding the second pair of secondary markers 110 formed parallel to the second pair of primary markers 106, and reference symbols 202c and 202d respectively indicate waveforms corresponding to the second pair of secondary markers 110. For each pair of secondary markers 110, when the focal plane is set in accordance with a pair of secondary markers 110, that pair of secondary markers 110 is detected with high resolution when light is radiated onto the substrate (i.e., radiated on the focal plane). As a result, distinct waveforms 204a and 204b corresponding to the first pair of secondary markers 110, as shown in FIG. 10A, are output, and the center position of distance I between waveforms 204a and 204b may be measured. Also as a result, distinct waveforms 202c and 202d corresponding to the second pair of secondary markers 110, as shown in FIG. 10B, are output, and the center position of distance J between waveforms 202c and 202d may be measured. A center position for secondary marker 110 may be found in accordance with the third and fourth waveforms.

As described above, the focal plane is respectively set in accordance with the first pair of primary markers 102, the second pair of primary markers 106, and first and second pairs of secondary markers 110, and waveforms corresponding to these pairs of markers are detected. In addition, a center of primary marker 102, 106 is detected using the waveforms corresponding to the first pair of primary markers 102 and the second pair of primary markers 106, and a center of the secondary marker is detected using the waveforms respectively corresponding to pairs of secondary markers 110. Further, by detecting the difference (i.e., the error) between the centers of the primary marker and the secondary marker, the overlay accuracy between primary marker 102, 106 and the subsequently formed secondary marker 110 is measured.

In obtaining the overlay accuracy between an upper marker and two lower markers respectively formed on different material layers, a primary marker (i.e., the lower markers) comprising a first pair of primary markers and a second pair of primary markers is formed by arranging the first pair of primary markers and the second pair of primary markers perpendicular to each other (e.g., parallel to the Y-axis and the X-axis, respectively) and forming the first and second pairs of primary markers on different material layers, respectively; and a secondary marker (i.e., the upper marker) is formed on the layers in which the first and second pairs of primary markers are formed. In addition, waveforms for each pair of primary markers are detected by respectively setting a focal plane in accordance with the first and second pairs of primary markers. Further, a center position of the entire primary marker is detected using the detected waveforms corresponding to the first and second pairs of primary markers. Next, waveforms corresponding to pairs of secondary markers formed above the primary marker are detected by respectively setting the focal plane in accordance with the pairs of secondary markers, and the center of the secondary marker is then detected. Then, an error between the centers of the entire primary marker and the secondary marker is detected, thereby exactly measuring the overlay accuracy between the primary marker formed on multiple layers and the secondary marker formed on the primary marker.

Although the invention has been described with reference embodiments thereof, it will be understood that the scope of the invention is not limited to the disclosed embodiments. Rather, various modifications may be made to the disclosed embodiments by one of ordinary skill in the art without materially departing from the scope of the invention as defined by the accompanying claims.

What is claimed is:

1. An overlay marker adapted for use in fabricating a semiconductor device, the semiconductor device comprising sequentially disposed first, second, and third material layers, and the overlay marker comprising:
a primary marker comprising;
a first pair of primary markers oriented in a first direction and disposed facing each other on the first material layer, and
a second pair of primary markers oriented in a second direction and disposed facing each other on the second material layer; and,
a secondary marker disposed on the third material layer and comprising;
a first pair of secondary markers disposed facing each other between the first pair of first primary markers and in parallel with the first pair of primary markers, and
a second pair of secondary markers disposed facing each other between the second pair of primary markers and in parallel with the second pair of primary markers.

2. The overlay marker of claim 1, wherein the first material layer comprises a semiconductor substrate.

3. The overlay marker of claim 2, wherein the first pair of primary markers are formed from the semiconductor substrate.

4. The overlay marker of claim 1, wherein the first and second directions are orthogonal.

5. The overlay marker of claim 1, wherein the primary and secondary markers are each disposed in a rectangular shape.

6. A method for measuring overlay accuracy using an overlay marker adapted for use in fabricating a semiconductor device, the semiconductor device comprising sequentially disposed first, second, and third material layers, and the overlay marker comprising:
a primary marker comprising;
a first pair of primary markers oriented in a first direction and disposed facing each other on the first material layer, and
a second pair of primary markers oriented in a second direction and disposed facing each other on the second material layer; and,
a secondary marker disposed on the third material layer and comprising;
a first pair of secondary markers disposed facing each other between the first pair of first primary markers and in parallel with the first pair of primary markers, and
a second pair of secondary markers disposed facing each other between the second pair of primary markers and in parallel with the second pair of primary markers;
the method comprising:
finding a center of the primary marker;
finding a center of the secondary marker; and,
finding an error defined by the difference between the center of the primary marker and the center of the secondary marker.

7. The method of claim 6, wherein finding a center of the primary marker comprises:
finding a center of the first pair of primary markers;
finding a center of the second pair of primary markers;
correlating the center of the first pair of primary markers with the center of the second pair of primary markers.

8. The method of claim 7, wherein finding the center of the first pair of primary markers comprises:
setting a focal plane in accordance with the first pair of primary markers;
outputting a first waveform corresponding to the first pair of primary markers; and,
analyzing the first waveform to find the center of the first pair of primary markers.

9. The method of claim 8, further comprising:
radiating light on the focal plane using a light source, wherein the light source is a visible ray or a laser.

10. The method of claim 9, wherein the visible ray is a g-line of 436 nm or a green light of 547 nm.

11. The method of claim 9, wherein the laser is a He-Ne laser of 633 nm or a He-Cd laser of 442 nm.

12. The method of claim 7, wherein finding the center of the second pair of primary markers comprises:
setting a focal plane in accordance with the second pair of primary markers;
outputting a second waveform corresponding to the second pair of primary markers; and,
analyzing the second waveform to find the center of the second pair of primary markers.

13. The method of claim 12, further comprising:
radiating light on the focal plane using a light source, wherein the light source is a visible ray or a laser.

14. The method of claim 13, wherein the visible ray is a g-line of 436 nm or a green light of 547 nm.

15. The method of claim 13, wherein the laser is a He-Ne laser of 633 nm or a He-Cd laser of 442 nm.

16. The method of claim 6, wherein finding a center of the secondary marker comprises:
setting a focal plane in accordance with the first pair of secondary markers;
outputting a third waveform corresponding to the first pair of secondary markers;
setting a focal plane in accordance with the second pair of secondary markers;
outputting a fourth waveform corresponding to the second pair of secondary markers; and,
analyzing the third and fourth waveforms to find the center of the secondary markers.

17. The method of claim 16, further comprising:
radiating light on the focal plane using a light source, wherein the light source is a visible ray or a laser.

18. The method of claim 6, wherein the primary marker is formed from a conductive film.

19. The method of claim 6, wherein the secondary marker is formed from a photoresist material.
